(19) United States
(12) Patent Application Publication
(10) Pub. No.: US 2022/0187517 A1
(43) Pub. Date: Jun. 16, 2022

(54) WAVELENGTH CONVERSION MEMBER, BACKLIGHT UNIT, IMAGE DISPLAY DEVICE, AND WAVELENGTH CONVERSION RESIN COMPOSITION

(71) Applicant: Showa Denko Materials Co., Ltd., Tokyo (JP)

(72) Inventors: Kaho YAMAGUCHI, Chiyoda-ku, Tokyo (JP); Masato NISHIMURA, Chiyoda-ku, Tokyo (JP); Kazuhito WATANABE, Chiyoda-ku, Tokyo (JP); Kouhei MUKAIGAITO, Chiyoda-ku, Tokyo (JP); Tooru KIKUCHI, Chiyoda-ku, Tokyo (JP)

(73) Assignee: Showa Denko Materials Co., Ltd., Tokyo (JP)

(21) Appl. No.: 17/436,652

(22) PCT Filed: Mar. 10, 2020
(86) PCT No.: PCT/JP2020/010306

§ 371 Date: Sep. 6, 2021

(30) Foreign Application Priority Data
Mar. 12, 2019 (JP) PCT/JP2019/010071

(51) Int. Cl. G02B 5/20; G02F 1/1335; C09K 11/88; C09K 11/70; C08K 3/01; C08K 7/18; C08K 3/32; C08K 3/36; C08K 3/22; C08K 3/30

(52) U.S. Cl. CPC G02B 5/206; G02F 1/133514; C09K 11/883; C09K 11/70; C08K 3/01; G02F 1/133615; C08K 3/32; C08K 3/36; C08K 3/22; C08K 3/30; C08K 7/18

(57) ABSTRACT

A wavelength conversion member comprising: a quantum dot phosphor and a filler; and a cured resin product that contains the quantum dot phosphor and the filler. The content of the filler is 3 mass % or more with respect to the total amount of the cured resin product.

### TECHNICAL FIELD

The present invention relates to a wavelength conversion member, a backlight unit, an image display device and a wavelength conversion resin composition.

### BACKGROUND ART

In recent years, in the field of image display devices such as liquid crystal display devices, improvement in color reproducibility of displays has been required. Regarding a means for improving color reproducibility, a wavelength conversion member containing a quantum dot phosphor has been focused on as described in Published Japanese Translation No. 2013-544018 of the PCT International Publication and PCT International Publication No. WO 2016/052625.

A wavelength conversion member containing a quantum dot phosphor is arranged, for example, in a backlight unit of an image display device. When a wavelength conversion member containing a quantum dot phosphor that emits red light and a quantum dot phosphor that emits green light is used, if blue light as excitation light is emitted to the wavelength conversion member, white light can be obtained from red light and green light emitted from the quantum dot phosphors and blue light that has been transmitted through the wavelength conversion member. With the development of a wavelength conversion member containing a quantum dot phosphor, the color reproducibility of a display has increased from a conventional National Television System Committee (NTSC) ratio of 72% to an NTSC ratio of 100%.

Generally, a wavelength conversion member containing a quantum dot phosphor includes a cured product obtained by curing a curable composition containing a quantum dot phosphor. Curable compositions include those of a thermosetting type and a photocurable type, and in consideration of productivity, a photocurable curable composition is preferably used.

### SUMMARY OF INVENTION

### Technical Problem

When a curable composition containing a quantum dot phosphor is applied to a covering material, the applied curable composition being cured to produce a cured product as a wavelength conversion member, wrinkles are likely to occur in the cured product, and in particular, there is a problem that wrinkles in a cured product become more significant when a covering material is thinned in consideration of weight reduction, miniaturization, and the like.

The present disclosure has been made in view of the above circumstances, and an objective of the present disclosure is to provide a wavelength conversion member which contains a quantum dot phosphor and in which the occurrence of wrinkles in a cured resin product is minimized and a backlight unit using the same and an image display device. In addition, an objective of the present disclosure is to provide a wavelength conversion resin composition which contains a quantum dot phosphor and can form a cured resin product in which the occurrence of wrinkles is minimized.

### Solution to Problem

Specific solutions for achieving the above objectives are as follows.

<1> A wavelength conversion member including a quantum dot phosphor and a filler, and a cured resin product containing the quantum dot phosphor and the filler, wherein the content of the filler with respect to a total amount of the cured resin product is 3 mass % or more.
<2> The wavelength conversion member according to <1>,

wherein the filler includes a low refractive index filler having a refractive index of 2.3 or less.

<3> The wavelength conversion member according to <1> or <2>,

wherein the filler contains at least one selected from the group consisting of silica, alumina, barium sulfate, zinc oxide, calcium carbonate and an organic filler.

<4> The wavelength conversion member according to any one of <1> to <3>,

wherein the average particle size of the filler is 0.2 μm or more.

<5> The wavelength conversion member according to any one of <1> to <4>,

wherein, in a volume cumulative distribution curve obtained by a laser diffraction scattering method, a ratio (D10/D90) of a particle size (D10) of the filler at a cumulative 10% from a small particle size side to a particle size (D90) of the filler at a cumulative 90% from a small particle size side is 0.40 or less.

<6> The wavelength conversion member according to any one of <1> to <5>,

wherein the total light transmittance of the cured resin product is 55% or more.

<7> The wavelength conversion member according to any one of <1> to <6>,

wherein the cured resin product contains a sulfide structure.

<8> The wavelength conversion member according to any one of <1> to <6>,

wherein the cured resin product contains a sulfide structure bonded to two carbon atoms and both the carbon atoms bonded to the sulfide structure are primary carbon atoms.

<9> The wavelength conversion member according to any one of <1> to <8>, including

a covering material that covers at least a part of the cured resin product.

<10> The wavelength conversion member according to <9>,

wherein the covering material has a barrier property with respect to at least one of oxygen and water.

<11> The wavelength conversion member according to any one of <1> to <10>,

wherein no titanium oxide is contained or the content of titanium oxide with respect to a total amount of the cured resin product is less than 5 mass %.

<12> The wavelength conversion member according to any one of <1> to <11>,

wherein the content of the quantum dot phosphor with respect to a total amount of the cured resin product is 0.01 mass % to 1.0 mass %.

<13> The wavelength conversion member according to any one of <1> to <12>,

wherein, when the content of the quantum dot phosphor with respect to a total amount of the cured resin product is set as X, and the content of the filler with respect to a total amount of the cured resin product is set as Y, Y/X is 7.0 or more.

<14> The wavelength conversion member according to any one of <1> to <13>,

wherein the quantum dot phosphor includes a quantum dot phosphor R that emits red light and a quantum dot phosphor G that emits green light, and a content ratio of the quantum dot phosphor G with respect to the quantum dot phosphor R (quantum dot phosphor G/quantum dot phosphor R) is 1.0 to 4.0.

<15> A backlight unit including the wavelength conversion member according to any one of <1> to <14>, and a light source.
<16> An image display device including the backlight unit according to <15>.
<17> A wavelength conversion resin composition including a quantum dot phosphor, a filler, a multi-functional (meth)acrylate compound and a thiol compound including a multi-functional thiol compound, and in which the content of the filler is 3 mass % or more.
<18> The wavelength conversion resin composition according to <17>,

wherein the filler includes a low refractive index filler having a refractive index of 2.3 or less.

<19> The wavelength conversion resin composition according to <17> or <18>,

wherein the filler is at least one selected from the group consisting of silica, alumina, barium sulfate, zinc oxide, calcium carbonate and an organic filler.

<20> The wavelength conversion resin composition according to any one of <17> to <19>,

wherein the average particle size of the filler is 0.2 μm or more.

<21> The wavelength conversion resin composition according to any one of <17> to <20>,

wherein, in a volume cumulative distribution curve obtained by a laser diffraction scattering method, a ratio (D10/D90) of a particle size (D10) of the filler at a cumulative 10% from a small particle size side to a particle size (D90) of the filler at a cumulative 90% from a small particle size side is 0.40 or less.

<22> The wavelength conversion resin composition according to any one of <17> to <21>,

wherein the multi-functional thiol compound has at least one thiol group bonded to a primary carbon atom.

<23> The wavelength conversion resin composition according to any one of <17> to <22>,

wherein no titanium oxide is contained or the content of the titanium oxide with respect to a total amount of the wavelength conversion resin composition is less than 5 mass %.

<24> The wavelength conversion resin composition according to any one of <17> to <23>,

wherein the content of the quantum dot phosphor with respect to a total amount of the wavelength conversion resin composition is 0.01 mass % to 1.0 mass %.

<25> The wavelength conversion resin composition according to any one of <17> to <24>,

wherein, when the content of the quantum dot phosphor with respect to a total amount of the wavelength conversion resin composition is set as X, and the content of the filler with respect to a total amount of the wavelength conversion resin composition is set as Y, Y/X is 7.0 or more.

<26> The wavelength conversion resin composition according to any one of <17> to <25>,

wherein the quantum dot phosphor includes a quantum dot phosphor R that emits red light and a quantum dot phosphor G that emits green light, and a content ratio of the quantum dot phosphor G with respect to the quantum dot phosphor R (quantum dot phosphor G/quantum dot phosphor R) is 1.0 to 4.0.

<27> The wavelength conversion resin composition according to any one of <17> to <26>,

wherein a ratio of a total number of carbon-carbon double bonds in the multi-functional (meth)acrylate compound to a total number of thiol groups in the thiol compound (total number of carbon-carbon double bonds/total number of thiol groups) is 1.0 or more.

### Advantageous Effects of Invention

According to the present disclosure, it is possible to provide a wavelength conversion member which contains a quantum dot phosphor and in which the occurrence of wrinkles in a cured resin product is minimized and a backlight unit using the same and an image display device. In addition, the present disclosure can provide a wavelength conversion resin composition which contains a quantum dot phosphor and can form a cured resin product in which the occurrence of wrinkles is minimized.

### BRIEF DESCRIPTION OF DRAWINGS

FIG. 1 is a schematic cross-sectional view showing an example of a schematic configuration of a wavelength conversion member.

FIG. 2 is a diagram showing an example of a schematic configuration of a backlight unit.

FIG. 3 is a diagram showing an example of a schematic configuration of a liquid crystal display device.

### DESCRIPTION OF EMBODIMENTS

Forms for implementing the present invention will be described below in detail. However, the present invention is not limited to the following embodiments. In the following embodiments, constituent elements (also including elemental steps and the like) are not essential unless otherwise specified. The same applies to numerical values and ranges thereof, and they do not limit the present invention.

In the present disclosure, the term “process” includes not only a process independent of other processes but also a process even if the process cannot be clearly distinguished from other processes as long as an objective of the process is achieved.

In the present disclosure, when a numerical range is indicated using “to,” it means that numerical values stated before and after “to” are included as a minimum value and a maximum value.

In stepwise numerical ranges described in the present disclosure, an upper limit value or a lower limit value described in one numerical range may be replaced with an upper limit value or a lower limit value of other described stepwise numerical ranges. In addition, in the numerical ranges described in the present disclosure, the upper limit value or the lower limit value of the numerical range may be replaced with values shown in examples.

In the present disclosure, each component may contain a plurality of corresponding substances. When there are a plurality of types of substances corresponding to each component in the composition, a content or a content amount of each component means a total content or content amount of the plurality of types of substances present in the composition unless otherwise noted.

In the present disclosure, a plurality of types of particles corresponding to each component may be included. When there are a plurality of types of particles corresponding to each component in the composition, the particle size of each component means a value for a mixture including the plurality of types of particles present in the composition unless otherwise noted.

In the present disclosure, the term “layer” or “film” means, when a region in which the layer or film is present is observed, not only a case in which it is formed over the entire region but also a case in which it is formed only in a part of the region.

In the present disclosure, the term “laminating” refers to laminating layers, combining two or more layers, or two or more layers that are removable.

In the present disclosure, “(meth)acryloyl group” refers to at least one of an acryloyl group and a methacryloyl group, “(meth)acrylate” refers to at least one of acrylate and methacrylate, and “(meth)allyl” refers to at least one of allyl and methallyl.

In the present disclosure, the numerical range of a preferable content of the quantum dot phosphor, the filler and the like of the wavelength conversion resin composition is the same as the numerical range of a preferable content of the quantum dot phosphor, the filler, and the like of each component in the cured resin product.

In the present disclosure, the average particle size of the filler can be measured as follows.

The filler obtained after the resin content in the cured resin product is removed by decomposition, combustion or the like or the filler extracted from the wavelength conversion resin composition is dispersed in purified water containing a surfactant to obtain a dispersion. In a volume-based particle size distribution curve measured using this dispersion by a laser diffraction type particle size distribution measurement device (for example, SALD-3000J commercially available from Shimadzu Corporation), a value (median diameter (D50)) at a cumulative 50% from the small diameter side is an average particle size of the filler. A method of extracting a filler from the wavelength conversion resin composition may be, for example, a method in which the wavelength conversion resin composition is diluted in a liquid medium, and a filler is precipitated and collected according to a centrifugation process or the like.

In the present disclosure, the D10/D90 of the filler is a ratio of the particle size (D10) of the filler at a cumulative 10% from the small particle size side to the particle size (D90) of the filler at a cumulative 90% from the small particle size side in a volume cumulative distribution curve obtained by a laser diffraction scattering method. The D10/D90 can be measured using a laser diffraction type particle size distribution measurement device (for example, SALD-3000J commercially available from Shimadzu Corporation) in the same manner as in the above D50.

In the present disclosure, the refractive index of the filler is a refractive index of the filler with respect to the D line (589.3 nm).

### <Wavelength Conversion Member>

The wavelength conversion member of the present disclosure contains a quantum dot phosphor and a filler, and a cured resin product containing the quantum dot phosphor and the filler, and the content of the filler with respect to a total amount of the cured resin product is 3 mass % or more. In the wavelength conversion member of the present disclosure, it is thought that, when the content of the filler with respect to a total amount of the cured resin product is 3 mass % or more, the occurrence of wrinkles in the cured resin product is minimized. The reason for this is inferred to be that the amount of curable compounds such as multi-functional (meth)acrylate compounds and thiol compounds including multi-functional thiol compounds in the curable composition (for example, a wavelength conversion resin composition to be described below) used for producing a cured resin product can be reduced, and as a result, shrinkage of the curable compound during curing can be minimized.

The wavelength conversion member of the present disclosure may contain other constituent elements such as a covering material to be described below as necessary.

The cured resin product according to the present disclosure may be a cured product of the wavelength conversion resin composition of the present disclosure to be described below.

The wavelength conversion member of the present disclosure is appropriately used for image display.

The wavelength conversion member of the present disclosure contains a quantum dot phosphor and a filler, and the quantum dot phosphor and the filler are contained in the cured resin product.

Details of the quantum dot phosphor and the filler contained in the cured resin product are the same as those to be described below in the section of the wavelength conversion resin composition.

For the filler contained in the cured resin product, the average particle size (D50), the D10/D90, and the like may be measured by the above method using the filler obtained after the cured resin product is fired, and the resin content is removed by decomposition, combustion, or the like.

In addition, the content of the filler in the cured resin product may be determined using the mass of the filler obtained after the cured resin product is fired, and the resin content is removed by decomposition, combustion or the like, and the mass of the cured resin product measured in advance.

In the wavelength conversion member of the present disclosure, the cured resin product may contain a sulfide structure or an alicyclic structure in order to obtain excellent moisture and heat resistance and minimize the occurrence of wrinkles. The cured resin product containing a sulfide structure may be formed, for example, by a polymerization reaction of a thiol group in a compound containing a thiol group and a carbon-carbon double bond in a compound containing a carbon-carbon double bond. The alicyclic structure that can be contained in the cured resin product may be derived from the structure contained in the compound containing a carbon-carbon double bond.

In order to obtain better moisture and heat resistance, the cured resin product has a sulfide structure bonded to two carbon atoms, and both carbon atoms bonded to the sulfide structure are preferably primary carbon atoms. The cured resin product containing a sulfide structure bonded to two primary carbon atoms may be formed, for example, by a polymerization reaction of a thiol group in a compound containing a thiol group bonded to a primary carbon atom and a carbon-carbon double bond in a compound containing a carbon-carbon double bond. When the compound containing a thiol group bonded to a primary carbon atom is used in a polymerization reaction, it is easier to obtain a cured resin product in which the composition used for producing the cured resin product has excellent curability and the residual liquid portion after curing is minimized than when a compound that does not contain a thiol group bonded to a primary carbon atom but contains a thiol group bonded to a secondary carbon atom or a tertiary carbon atom is used in a polymerization reaction.

The alicyclic structure that can be contained in the cured resin product is not particularly limited, and may be a monocyclic structure or a polycyclic structure such as a bicyclic structure and a tricyclic structure. Specific examples of alicyclic structures include monocyclic structures such as a cyclobutane framework, a cyclopentane framework, and a cyclohexane framework, and polycyclic structures such as a tricyclodecane framework, a cyclohexane framework, a 1,3-adamantane framework, a hydrogenated bisphenol A framework, a hydrogenated bisphenol F framework, a hydrogenated bisphenol S framework, and an isobornyl framework. Among these, a polycyclic structure is preferable, a tricyclodecane framework or an isobornyl framework is more preferable, and a tricyclodecane framework is still more preferable.

The alicyclic structure that can be contained in the cured resin product may be of one type alone or at least two types, and is preferably of at least two types.

When at least two types of alicyclic structures are contained in the cured resin product, examples of a combination of alicyclic structures include a combination of a tricyclodecane framework and an isobornyl framework, and a combination of a hydrogenated bisphenol A framework and an isobornyl framework. Among these, a combination of a tricyclodecane framework and an isobornyl framework is preferable in consideration of the luminous efficiency, brightness and moisture and heat resistance.

The ratio of an amount of the polycyclic structure to an amount of the alicyclic structure is not particularly limited, and the mol-based proportion of the polycyclic structure is preferably 70 mol % to 100 mol %, more preferably 80 mol % to 100 mol %, and still more preferably 90 mol % to 100 mol %.

When a combination of a tricyclodecane framework and an isobornyl framework is used as an alicyclic structure, a mol-based content ratio of the tricyclodecane framework to that of the isobornyl framework (tricyclodecane framework/isobornyl framework) is preferably 5 to 20, more preferably 5 to 18, and still more preferably 5 to 15 in consideration of moisture and heat resistance.

The ratio of an amount of the polycyclic structure to an amount of the alicyclic structure and the mol-based content ratio of the tricyclodecane framework to that of the isobornyl framework may be calculated from the content amount of components contained in the wavelength conversion resin composition used for producing the cured resin product. For example, the mol-based content ratio of the compound having a tricyclodecane framework to that of the compound having an isobornyl framework is the same as the mol-based content ratio of the tricyclodecane framework to that of the isobornyl framework.

The cured resin product may contain an ester structure. Examples of compounds containing a carbon-carbon double bond which is a source of the cured resin product include a (meth)allyl compound having a (meth)allyl group and a (meth)acrylate compound having a (meth)acryloyl group. A (meth)acrylate compound tends to have a stronger polymerization reaction activity than a (meth)allyl compound. The fact that a cured resin product contains an ester structure suggests that a (meth)acrylate compound has been used as a compound containing a carbon-carbon double bond. The cured resin product formed using a (meth)acrylate compound tends to have a higher glass transition temperature than the cured resin product formed using the (meth)allyl compound.

The shape of the wavelength conversion member is not particularly limited, and examples thereof include a film shape and a lens shape. When the wavelength conversion member is applied to a backlight unit to be described below, the wavelength conversion member preferably has a film shape.

When the wavelength conversion member has a film shape, the average thickness of the cured resin product in the wavelength conversion member is, for example, preferably 40 μm to 200 μm, more preferably 50 μm to 150 μm, and still more preferably 50 μm to 120 μm. When the average thickness of the cured resin product is 50 μm or more, the wavelength conversion efficiency tends to be further improved, and when the average thickness is 200 μm or less, if the wavelength conversion member is applied to a backlight unit to be described below, the backlight unit tends to be thinner.

For example, the average thickness of the film-like cured resin product is obtained as an arithmetic average value of the thicknesses at three arbitrary points measured using a micrometer.

In addition, when the average thickness of the cured resin product is obtained from a film-like and multi-layer wavelength conversion member, the average thickness of the cured resin product is obtained as an arithmetic average value of the thicknesses at three arbitrary points measured by observing the cross section of the cured resin product using a scanning electron microscope (SEM).

The wavelength conversion member may be obtained by curing one type of wavelength conversion resin composition, or curing two or more types of wavelength conversion resin compositions. For example, when the wavelength conversion member has a film shape, the wavelength conversion member may be obtained by laminating a first cured product layer obtained by curing a wavelength conversion resin composition containing a first quantum dot phosphor and a second cured product layer obtained by curing a wavelength conversion resin composition containing a second quantum dot phosphor having different emission characteristics from the first quantum dot phosphor.

The wavelength conversion member can be obtained by forming a coating film, a molded product, or the like of a wavelength conversion resin composition, performing a drying treatment as necessary, and then emitting active energy rays such as UV rays. The wavelength and emission amount of the active energy rays can be appropriately set according to the composition of the wavelength conversion resin composition. In one embodiment, UV rays having a wavelength of 280 nm to 400 nm are emitted in an emission amount of 100 mJ/cm² to 5,000 mJ/cm². Examples of UV sources include a low pressure mercury lamp, an intermediate-pressure mercury lamp, a high pressure mercury lamp, an ultra-high pressure mercury lamp, a carbon arc lamp, a metal halide lamp, a xenon lamp, a chemical lamp, a black light lamp, and a microwave excited mercury lamp.

In order to further improve the adhesion, the cured resin product contained in the wavelength conversion member has a loss tangent (tan δ) measured under conditions of a frequency of 10 Hz and a temperature of 25° C. according to dynamic viscoelasticity measurement which is preferably 0.4 to 1.5, more preferably 0.4 to 1.2, and still more preferably 0.4 to 0.6. The loss tangent (tan δ) of the cured resin product can be measured using a dynamic viscoelasticity measurement device (for example, commercially available from Rheometric Scientific, Solid Analyzer RSA-III).

In addition, in order to further improve the adhesion, heat resistance, and moisture and heat resistance, the glass transition temperature (Tg) of the cured resin product is preferably 85° C. or higher, more preferably 85° C. to 160° C., and still more preferably 90° C. to 120° C. The glass transition temperature (Tg) of the cured resin product can be measured using a dynamic viscoelasticity measurement device (for example, commercially available from Rheometric Scientific, Solid Analyzer RSA-III) under a condition of a frequency of 10 Hz.

In addition, in order to further improve the adhesion, heat resistance, and moisture and heat resistance, the cured resin product has a storage elastic modulus measured under conditions of a frequency of 10 Hz and a temperature of 25° C. which is preferably 1×10⁷ Pa to 1×10¹⁰ Pa, more preferably 5×10⁷ Pa to 1×10¹⁰ Pa, and still more preferably 5×10⁷ Pa to 5×10⁹ Pa. The storage elastic modulus of the cured resin product can be measured using a dynamic viscoelasticity measurement device (for example, commercially available from Rheometric Scientific, Solid Analyzer RSA-III).

The wavelength conversion member of the present disclosure may contain a covering material that covers at least a part of the cured resin product. For example, when the cured resin product has a film shape, one surface or both surfaces of the film-like cured resin product may be covered with a film-like covering material.

In order to minimize decrease in luminous efficiency of the quantum dot phosphor, the covering material preferably has a barrier property with respect to at least one of oxygen and water, and more preferably has a barrier property with respect to both oxygen and water. The covering material having a barrier property with respect to at least one of oxygen and water is not particularly limited, and a known covering material such as a barrier film having an inorganic layer can be used.

When the covering material has a film shape, when the covering material has a film shape, the average thickness of the covering material is, for example, preferably 10 μm to 150 μm, more preferably 10 μm to 125 μm, and still more preferably 10 μm to 100 μm. When the average thickness is 100 μm or more, a function such as a barrier property tends to be sufficient, and when the average thickness is 150 μm or less, decrease in light transmittance tends to be minimized.

The average thickness of the film-like covering material is obtained in the same manner as in the film-like cured resin product.

The oxygen permeability of the covering material is, for example, preferably 0.5 mL/(m²·24 h·atm) or less, more preferably 0.3 mL/(m²·24 h·atm) or less, and still more preferably 0.1 mL/(m²·24 h·atm) or less. The oxygen permeability of the covering material can be measured using an oxygen permeability measurement device (for example, OX-TRAN commercially available from MOCON) under conditions of a temperature of 23° C. and a relative humidity 65%.

In addition, the water vapor permeability of the covering material is, for example, preferably 5×10⁻² g/(m²·24 h·Pa) or less, more preferably 1×10⁻² g/(m²·24 h·Pa) or less, and still more preferably 5×10⁻³ g/(m²·24 h·Pa) or less. The water vapor permeability of the covering material can be measured using a water vapor permeability measurement device (for example, AQUATRAN commercially available from MOCON) under conditions of a temperature of 40° C. and a relative humidity of 90%.

In order to further improve light utilization efficiency and improve brightness, the total light transmittance of the wavelength conversion member of the present disclosure is preferably 55% or more, more preferably 60% or more, and still more preferably 65% or more. The total light transmittance of the wavelength conversion member can be measured according to a measurement method of JIS K 7136:2000.

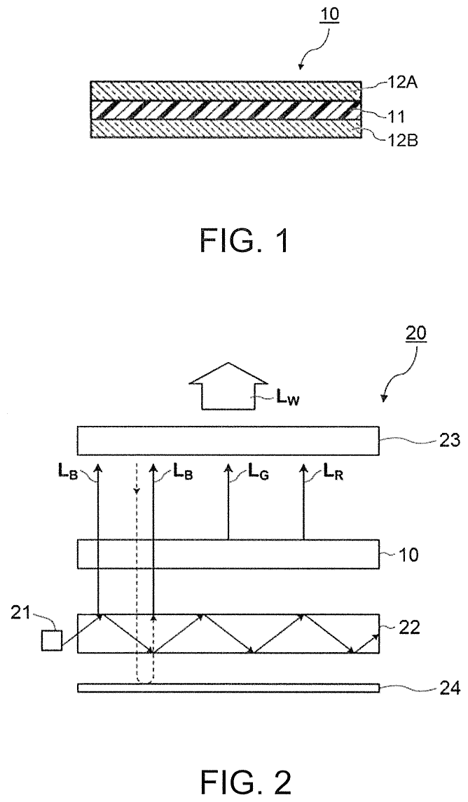

FIG. 1 shows an example of a schematic configuration of the wavelength conversion member. However, the wavelength conversion member of the present disclosure is not limited to the configuration in FIG. 1. In addition, the sizes of the cured product layer and the covering material in FIG. 1 are conceptual, and the relative relationship of the sizes is not limited thereto. Here, in the drawings, the same members are denoted with the same reference numerals and redundant descriptions may be omitted.

A wavelength conversion member 10 shown in FIG. 1 includes a cured product layer 11 as a film-like cured resin product and the film-like covering materials 12A and 12B provided on both surfaces of the cured product layer 11. The types and the average thicknesses of the covering material 12A and the covering material 12B may be the same as or different from each other.

The wavelength conversion member having a configuration shown in FIG. 1 can be produced by, for example, the following known production method.

First, a wavelength conversion resin composition to be described below is applied to a surface of a film-like covering material (hereinafter referred to as a “first covering material”) that is continuously transported to form a coating film. A method of applying a wavelength conversion resin composition is not particularly limited, and examples thereof include a die coating method, a curtain coating method, an extrusion coating method, a rod coating method, and a roll coating method.

Next, the film-like covering material (hereinafter referred to as a “second covering material”) that is continuously transported is attached to the coating film of the wavelength conversion resin composition.

Next, when active energy rays are emitted from the side of the covering material that can transmit active energy rays between the first covering material and the second covering material, a coating film is cured to form a cured product layer. Then, when cutting out into a specified size is performed, the wavelength conversion member having the configuration shown in FIG. 1 can be obtained.

Here, when neither the first covering material nor the second covering material can transmit active energy rays, active energy rays are emitted to the coating film before the second covering material is attached, and a cured product layer may be formed.

### <Backlight Unit>

The backlight unit of the present disclosure includes the above wavelength conversion member of the present disclosure and a light source.

In order to improve color reproducibility, the backlight unit is preferably a multi-wavelength light source. In one preferable embodiment, a backlight unit that emits blue light having an emission center wavelength in a wavelength range of 430 nm to 480 nm and an emission intensity peak having a half-value width of 100 nm or less, green light having an emission center wavelength in a wavelength range of 520 nm to 560 nm and an emission intensity peak having a half-value width of 100 nm or less, and red light having an emission center wavelength in a wavelength range of 600 nm to 680 nm and an emission intensity peak having a half-value width of 100 nm or less may be exemplified. Here, the half-value width of the emission intensity peak means a peak width in which the height is ½ of the height of the peak.

In order to further improve color reproducibility, the emission center wavelength of blue light which is emitted from the backlight unit is preferably in a range of 440 nm to 475 nm. For the same reason, the emission center wavelength of green light which is emitted from the backlight unit is preferably in a range of 520 nm to 545 nm. In addition, for the same reason, the emission center wavelength of red light which is emitted from the backlight unit is preferably in a range of 610 nm to 640 nm.

In addition, in order to further improve color reproducibility, half-value widths of emission intensity peaks of blue light, green light, and red light which are emitted from the backlight unit are all preferably 80 nm or less, more preferably 50 nm or less, still more preferably 40 nm or less, particularly preferably 30 nm or less, and most preferably 25 nm or less.

Regarding the light source of the backlight unit, for example, a light source that emits blue light having an emission center wavelength in a wavelength range of 430 nm to 480 nm can be used. Examples of light sources include a light emitting diode (LED) and a laser. When a light source that emits blue light is used, the wavelength conversion member preferably contains at least a quantum dot phosphor R that emits red light and a quantum dot phosphor G that emits green light. Therefore, white light can be obtained from red light and green light emitted from the wavelength conversion member and blue light that has been transmitted through the wavelength conversion member.

In addition, regarding the light source of the backlight unit, for example, a light source that emits ultraviolet light having an emission center wavelength in a wavelength range of 300 nm to 430 nm can be used. Examples of light sources include an LED and a laser. When a light source that emits ultraviolet light is used, the wavelength conversion member preferably contains a quantum dot phosphor R and a quantum dot phosphor G, and also a quantum dot phosphor B that emits blue light excited by excitation light. Therefore, white light can be obtained from red light, green light, and blue light emitted from the wavelength conversion member.

The backlight unit of the present disclosure may be of an edge light type or a direct type.

FIG. 2 shows an example of a schematic configuration of an edge light type backlight unit. However, the backlight unit of the present disclosure is not limited to the configuration in FIG. 2. In addition, the sizes of the members in FIG. 2 are conceptual, and the relative relationship of sizes between the members is not limited thereto.

A backlight unit 20 shown in FIG. 2 includes a light source 21 that emits blue light L_{B}, a light-guiding plate 22 that guides and emits blue light L_{B} emitted from the light source 21, the wavelength conversion member 10 that is arranged to face the light-guiding plate 22, a retroreflective member 23 that is arranged to face the light-guiding plate 22 with the wavelength conversion member 10 therebetween, and a reflective plate 24 that is arranged to face the wavelength conversion member 10 with the light-guiding plate 22 therebetween. The wavelength conversion member 10 emits red light L_{R} and green light L_{G} using a part of the blue light L_{B} as excitation light, and emits the red light L_{R} and the green light L_{G}, and blue light L_{B} that has not become excitation light. According to the red light L_{R}, green light L_{G}, and blue light L_{B}, white light L_{W} is emitted from the retroreflective member 23.

### <Image Display Device>

The image display device of the present disclosure includes the above backlight unit of the present disclosure. The image display device is not particularly limited, and examples thereof include a liquid crystal display device.

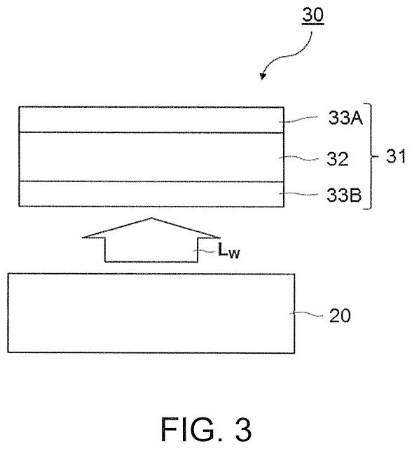

FIG. 3 shows an example of a schematic configuration of a liquid crystal display device. However, the liquid crystal display device of the present disclosure is not limited to the configuration in FIG. 3. In addition, the sizes of the members in FIG. 3 are conceptual, and the relative relationship of sizes between the members is not limited thereto.

A liquid crystal display device 30 shown in FIG. 3 includes the backlight unit 20, and a liquid crystal cell unit 31 that is arranged to face the backlight unit 20. The liquid crystal cell unit 31 has a configuration in which a liquid crystal cell 32 is arranged between a polarization plate 33A and a polarization plate 33B

The drive method of the liquid crystal cell 32 is not particularly limited, and examples thereof include a twisted Nematic (TN) method, a super twisted nematic (STN) method, a vertical alignment (VA) method, an in-plane-switching (IPS) method, and an optically compensated birefringence (OCB) method.

### <Wavelength Conversion Resin Composition>

The wavelength conversion resin composition of the present disclosure contains a quantum dot phosphor, a filler, a multi-functional (meth)acrylate and a thiol compound including a multi-functional thiol compound, and the content of the filler is 3 mass % or more. The wavelength conversion resin composition of the present disclosure may further contain other components as necessary. When the wavelength conversion resin composition of the present disclosure has the above configuration, it is possible to minimize the occurrence of wrinkles in the cured resin product.

### (Quantum Dot Phosphor)

The wavelength conversion resin composition contains a quantum dot phosphor. The quantum dot phosphor is not particularly limited, and examples thereof include particles containing at least one selected from the group consisting of Group II-VI compounds, Group III-V compounds, Group IV-VI compounds, and Group IV compounds. In consideration of luminous efficiency, the quantum dot phosphor preferably contains a compound containing at least one of Cd and In.

Specific examples of Group II-VI compounds include CdSe, CdTe, CdS, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe.

Specific examples of Group III-V compounds include GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb.

Specific examples of Group IV-VI compounds include SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe.

Specific examples of Group IV compounds include Si, Ge, SiC, and SiGe.

The quantum dot phosphor preferably has a core-shell structure. When the band gap of the compound constituting the shell is set to be wider than the band gap of the compound constituting the core, it is possible to further improve quantum efficiency of the quantum dot phosphor. Examples of combinations of a core and a shell (core/shell) include CdSe/ZnS, InP/ZnS, PbSe/PbS, CdSe/CdS, CdTe/CdS, and CdTe/ZnS.

In addition, the quantum dot phosphor may have a so-called core multi-shell structure in which the shell has a multi-layer structure. When one layer or two or more layers of a shell having a narrow band gap are laminated on a core having a wide band gap, and additionally, a shell having a wide band gap is laminated on the shell, it is possible to further improve quantum efficiency of the quantum dot phosphor.

The wavelength conversion resin composition may contain one type of quantum dot phosphor alone or two or more types of quantum dot phosphors in combination. Examples of a mode in which two or more types of quantum dot phosphors are combined include a mode in which two or more types of quantum dot phosphors having different components but having the same average particle size are contained, a mode in which two or more types of quantum dot phosphors having different average particle sizes but having the same component are contained, and a mode in which two or more types of quantum dot phosphors having different components and average particle sizes are contained. When at least one of the component and the average particle size of the quantum dot phosphor is changed, it is possible to change the emission center wavelength of the quantum dot phosphor.

For example, the wavelength conversion resin composition may contain a quantum dot phosphor G having an emission center wavelength in a green wavelength range of 520 nm to 560 nm and a quantum dot phosphor R having an emission center wavelength in a red wavelength range of 600 nm to 680 nm. When excitation light in a blue wavelength range of 430 nm to 480 nm is emitted to the cured resin product of the wavelength conversion resin composition containing the quantum dot phosphor G and the quantum dot phosphor R, green light and red light are emitted from the quantum dot phosphor G and the quantum dot phosphor R. As a result, white light can be obtained by green light and red light emitted from the quantum dot phosphor G and the quantum dot phosphor R and blue light that transmitted through the cured resin product.

The quantum dot phosphor may be used in a quantum dot phosphor dispersion state in which it is dispersed in a dispersion medium. Examples of dispersion mediums in which the quantum dot phosphor is dispersed include various organic solvents and monofunctional (meth)acrylate compounds.

Examples of organic solvents that can be used as the dispersion medium include water, acetone, ethyl acetate, toluene, and n-hexane.

The monofunctional (meth)acrylate compound that can be used as the dispersion medium is not particularly limited as long as it is a liquid at room temperature (25° C.), and examples thereof include monofunctional (meth)acrylate compounds having an alicyclic structure. The alicyclic structure contained in the monofunctional (meth)acrylate compound is not particularly limited, and it may be a monocyclic structure or a polycyclic structure such as a bicyclic structure and a tricyclic structure. Specific examples of monofunctional (meth)acrylate compounds include isobornyl (meth)acrylate and dicyclopentanyl (meth)acrylate.

Among these, the dispersion medium is preferably a monofunctional (meth)acrylate compound, more preferably a monofunctional (meth)acrylate compound having an alicyclic structure, still more preferably a monofunctional (meth)acrylate compound having a polycyclic structure, particularly preferably isobornyl (meth)acrylate and dicyclopentanyl (meth)acrylate, and most preferably isobornyl (meth)acrylate because there is no need to provide a process of volatilizing the dispersion medium when the wavelength conversion resin composition is cured.

When a monofunctional (meth)acrylate compound is used as the dispersion medium, a mass-based content ratio of a monofunctional (meth)acrylate compound to that of a multi-functional (meth)acrylate compound (monofunctional (meth)acrylate compound/multi-functional (meth)acrylate compound) is preferably 0.01 to 0.30, more preferably 0.02 to 0.20, and still more preferably 0.05 to 0.20.

When a monofunctional (meth)acrylate compound is used as a dispersion medium, in consideration of moisture and heat resistance, as a combination of the monofunctional (meth)acrylate compound and the multi-functional (meth)acrylate compound, the multi-functional (meth)acrylate compound contains a compound having a tricyclodecane framework, and the monofunctional (meth)acrylate compound preferably contains a compound having an isobornyl framework.

In consideration of moisture and heat resistance, the mol-based content ratio of the compound having a tricyclodecane framework to that of the compound having an isobornyl framework (compound having a tricyclodecane framework/compound having an isobornyl framework) is preferably 5 to 20, more preferably 5 to 18, and still more preferably 5 to 15.

The mass-based ratio of the quantum dot phosphor in the quantum dot phosphor dispersion is preferably 1 mass % to 30 mass %, more preferably 1 mass % to 20 mass %, and still more preferably 1 mass % to 10 mass %.

When the mass-based ratio of the quantum dot phosphor in the quantum dot phosphor dispersion is 1 mass % to 20 mass %, the content of the quantum dot phosphor dispersion in the wavelength conversion resin composition with respect to the total amount of the wavelength conversion resin composition is, for example, preferably 1 mass % to 10 mass %, more preferably 4 mass % to 10 mass %, and still more preferably 4 mass % to 7 mass %.

In addition, the content of the quantum dot phosphor in the wavelength conversion resin composition with respect to the total amount of the wavelength conversion resin composition is, for example, preferably 0.01 mass % to 1.0 mass %, more preferably 0.05 mass % to 0.5 mass %, and still more preferably 0.1 mass % to 0.5 mass %. When the content of the quantum dot phosphor is 0.01 mass % or more, a sufficient emission intensity when excitation light is emitted to the cured resin product tends to be obtained, and when the content of the quantum dot phosphor is 1.0 mass % or less, aggregation of the quantum dot phosphor tends to be minimized.

In consideration of brightness, the quantum dot phosphor includes a quantum dot phosphor R that emits red light and a quantum dot phosphor G that emits green light, and the content ratio of the quantum dot phosphor G with respect to the quantum dot phosphor R (quantum dot phosphor G/quantum dot phosphor R) is preferably 1.0 to 4.0, more preferably 1.2 to 3.5, and still more preferably 1.5 to 3.0.

### (Filler)

The wavelength conversion resin composition contains a filler, and the content of the filler with respect to the total amount of the wavelength conversion resin composition is 3 mass % or more.

In order to minimize the decrease in brightness, the filler preferably includes a low refractive index filler having a refractive index of 2.3 or less. In order to minimize the decrease in brightness more appropriately, the low refractive index filler is preferably 2.1 or less, more preferably 2.0 or less, still more preferably 1.8 or less, and particularly preferably 1.6 or less.

When the filler includes a low refractive index filler, the content of the low refractive index filler with respect to the total amount of the filler is preferably 60 mass % to 100 mass %, more preferably 80 mass % to 100 mass %, and still more preferably 90 mass % to 100 mass %.

The filler preferably contains at least one selected from the group consisting of silica, alumina, barium sulfate, zinc oxide, calcium carbonate and an organic filler. In order to minimize the occurrence of wrinkles in the cured resin product and the decrease in brightness more appropriately, it is more preferably to contain at least one selected from the group consisting of silica, alumina, barium sulfate and calcium carbonate, and still more preferably to contain at least one selected from the group consisting of silica and alumina.

The filler may contain a high refractive index filler having a refractive index of more than 2.3. Examples of high refractive index fillers include titanium oxide.

When the filler contains a high refractive index filler, the content of the high refractive index filler with respect to the total amount of the filler is preferably 40 mass % or less, more preferably 20 mass % or less, and still more preferably 10 mass % or less.

In consideration of brightness, the filler does not contain a high refractive index filler such as titanium oxide, or the content of the high refractive index filler such as titanium oxide is preferably less than 5 mass % with respect to the total amount of the wavelength conversion resin composition. The content of the high refractive index filler such as titanium oxide with respect to the total amount of the wavelength conversion resin composition is more preferably 3 mass % or less.

In consideration of brightness, the average particle size of the filler is preferably 0.2 μm or more. In addition, the average particle size of the filler may be 0.2 μm to 40.0 μm, or 0.2 μm to 20.0 μm.

The D10/D90 of the filler may be 0.40 or less, 0.01 to 0.40, or 0.04 to 0.25. When the D10/D90 of the filler is 0.40 or less, the viscosity of the wavelength conversion resin composition increases due to an excellent filling ability of the filler and the occurrence of wrinkles tends to be appropriately minimized.

In consideration of minimizing the occurrence of wrinkles and brightness, the content of the filler with respect to the total amount of the wavelength conversion resin composition is preferably 5 mass % to 50 mass %, more preferably 10 mass % to 40 mass %, and still more preferably 15 mass % to 35 mass %.

In order to easily obtain a cured resin product in which the wavelength conversion resin composition has excellent curability and the residual liquid portion after curing is minimized, when the content of the quantum dot phosphor with respect to the total amount of the wavelength conversion resin composition is set as X and the content of the filler with respect to the total amount of the wavelength conversion resin composition is set as Y, Y/X is preferably 7.0 or more, more preferably 15 or more, and still more preferably 30 or more. In consideration of brightness, Y/X may be 100 or less.

When the Y/X is 7.0 or more, the amount of the quantum dot phosphor with respect to the filler is not too large. Therefore, the amount of active energy rays absorbed to the quantum dot phosphor when active energy rays such as UV rays are emitted to the wavelength conversion resin composition that is cured is minimized. Therefore, it is speculated that the residual liquid portion is less likely to occur after curing and the curability is excellent.

### (Multi-Functional (Meth)Acrylate Compound)

The wavelength conversion resin composition of the present disclosure contains a multi-functional (meth)acrylate compound. The multi-functional (meth)acrylate compound may be a compound having two or more (meth)acryloyl groups in one molecule.

Specific examples of multi-functional (meth)acrylic compounds include alkylene glycol di(meth)acrylates such as 1,4-butanediol di(meth)acrylate, 1,6-hexanediol di(meth)acrylate, and 1,9-nonanediol di(meth)acrylate; polyalkylene glycol di(meth)acrylates such as polyethylene glycol di(meth)acrylate, and polypropylene glycol di(meth)acrylate; tri(meth)acrylate compounds such as trimethylolpropane tri(meth)acrylate, ethylene oxide-added trimethylolpropane tri(meth)acrylate, and tris(2-acryloyloxyethyl)isocyanurate; tetra(meth)acrylate compounds such as ethylene oxide-added pentaerythritol tetra(meth)acrylate, trimethylolpropane tetra(meth)acrylate, and pentaerythritol tetra(meth)acrylate; and (meth)acrylate compounds having an alicyclic structure such as tricyclodecane dimethanol di(meth)acrylate, cyclohexanedimethanol di(meth)acrylate, 1,3-adamantane dimethanol di(meth)acrylate, hydrogenated bisphenol A (poly)ethoxydi(meth)acrylate, hydrogenated bisphenol A (poly)propoxydi(meth)acrylate, hydrogenated bisphenol F (poly)ethoxydi(meth)acrylate, hydrogenated bisphenol F (poly)propoxydi(meth)acrylate, hydrogenated bisphenol S (poly)ethoxydi(meth)acrylate, and hydrogenated bisphenol S (poly)propoxydi(meth)acrylate. Among these, in consideration of moisture and heat resistance, the multi-functional (meth)acrylate compound is preferably a (meth)acrylate compound having an alicyclic structure.

The multi-functional (meth)acrylate compound having an alicyclic structure is a multi-functional (meth)acrylate compound having an alicyclic structure in its framework and having two or more (meth)acryloyl groups in one molecule.

The alicyclic structure contained in the multi-functional (meth)acrylate compound having an alicyclic structure is not particularly limited, and may be a monocyclic structure or a polycyclic structure such as a bicyclic structure and a tricyclic structure.

The alicyclic structure contained in the multi-functional (meth)acrylate compound having an alicyclic structure preferably contains a polycyclic structure and more preferably contains a tricyclodecane framework. The multi-functional (meth)acrylate compound having a tricyclodecane framework in the alicyclic structure is preferably tricyclodecane dimethanol di(meth)acrylate.

The content of the multi-functional (meth)acrylate compound in the wavelength conversion resin composition with respect to the total amount of the wavelength conversion resin composition is, for example, preferably 10 mass % to 80 mass %, more preferably 30 mass % to 70 mass %, still more preferably 40 mass % to 65 mass %, and particularly preferably 45 mass % to 55 mass %. When the content of the multi-functional (meth)acrylate compound is within the above range, the moisture and heat resistance of the cured resin product tends to be further improved.

The wavelength conversion resin composition may contain one type of multi-functional (meth)acrylate compound alone or two or more types of multi-functional (meth)acrylate compounds in combination.

### (Thiol Compound)

The wavelength conversion resin composition may contain a thiol compound including a multi-functional thiol compound. When the wavelength conversion resin composition contains a thiol compound, an ene-thiol reaction occurs between the multi-functional (meth)acrylate compound and the thiol compound when the wavelength conversion resin composition is cured, and the moisture and heat resistance of the cured resin product tends to be further improved. In addition, when the wavelength conversion resin composition contains a multi-functional thiol compound, optical properties of the cured resin product tend to be further improved. In addition, when the wavelength conversion resin composition contains a multi-functional thiol compound, the occurrence of wrinkles in the cured resin product can be more appropriately minimized than when the wavelength conversion resin composition does not contain a multi-functional thiol compound.

Here, the composition containing a (meth)allyl compound and a thiol compound has poor storage stability in many cases, but the wavelength conversion resin composition of the present disclosure has excellent storage stability despite containing a thiol compound. This is speculated that this is because the wavelength conversion resin composition contains a multi-functional (meth)acrylate compound.

In order to further improve the moisture and heat resistance of the cured resin product, the multi-functional thiol compound preferably has at least one thiol group bonded to a primary carbon atom.

The wavelength conversion resin composition may contain both a multi-functional thiol compound having at least one thiol group bonded to a primary carbon atom and a multi-functional thiol compound having at least one thiol group bonded to a secondary carbon atom or a tertiary carbon atom.

In order to further improve the moisture and heat resistance of the cured resin product, in the wavelength conversion resin composition, the ratio of the multi-functional thiol compound having at least one thiol group bonded to a primary carbon atom with respect to a total amount of the multi-functional thiol compound is preferably 50 mass % to 100 mass %, more preferably 70 mass % to 100 mass %, and still more preferably 90 mass % to 100 mass %.

Specific examples of multi-functional thiol compounds include ethylene glycol bis(3-mercaptopropionate), diethylene glycol bis(3-mercaptopropionate), tetraethylene glycol bis(3-mercaptopropionate), 1,2-propylene glycol bis(3-mercaptopropionate), diethylene glycol bis(3-mercaptobutyrate), 1,4-butanediol bis(3-mercaptopropionate), 1,4-butanediol bis(3-mercaptobutyrate), 1,8-octanediol bis(3-mercaptopropionate), 1,8-octanediol bis(3-mercaptobutyrate), hexanediol bisthioglycolate, trimethylolpropane tris(3-mercaptopropionate), trimethylolpropane tris(3-mercaptobutyrate), trimethylolpropane tris(3-mercaptoisobutyrate), trimethylolpropane tris(2-mercaptoisobutyrate), trimethylolpropane tristhioglycolate, tris-[(3-mercaptopropionyloxy)-ethyl]-isocyanurate, trimethylolethane tris(3-mercaptobutyrate), pentaerythritol tetrakis(3-mercaptopropionate), pentaerythritol tetrakis(3-mercaptobutyrate), pentaerythritol tetrakis(3-mercaptoisobutyrate), pentaerythritol tetrakis(2-mercaptoisobutyrate), dipentaerythritol hexakis(3-mercaptopropionate), dipentaerythritol hexakis(2-mercaptopropionate), dipentaerythritol hexakis(3-mercaptobutyrate), dipentaerythritol hexakis(3-mercaptoisobutyrate), dipentaerythritol hexakis(2-mercaptoisobutyrate), pentaerythritol tetrakis thioglycolate, and dipentaerythritol hexakis thioglycolate.

In addition, the multi-functional thiol compound may be in a state of a thioether oligomer reacted with the multi-functional (meth)acrylate compound in advance.

The thioether oligomer can be obtained by addition polymerization of a multi-functional thiol compound and a multi-functional (meth)acrylate compound in the presence of a polymerization initiator. When the thioether oligomer is obtained by addition polymerization, the ratio of the number of equivalent of thiol groups of the multi-functional thiol compound to the number of equivalent of (meth)acryloyl groups of the multi-functional (meth)acrylate compound as raw materials (number of equivalent of thiol group/number of equivalent of (meth)acryloyl group) is, for example, preferably 3.0 to 3.3, more preferably 3.0 to 3.2, and still more preferably 3.05 to 3.15.

The weight average molecular weight of the thioether oligomer is, for example, preferably 3,000 to 10,000, more preferably 3,000 to 8,000, and still more preferably 4,000 to 6,000.

Here, the weight average molecular weight of the thioether oligomer is determined by performing conversion using a standard polystyrene calibration curve from a molecular weight distribution measured using gel permeation chromatography (GPC).

In addition, the thiol equivalent of the thioether oligomer is, for example, preferably 200 g/eq to 400 g/eq, more preferably 250 g/eq to 350 g/eq, and still more preferably 250 g/eq to 270 g/eq.

Here, the thiol equivalent of the thioether oligomer can be measured by the following iodine titration method.

0.2 g of a measurement sample is accurately weighed and 20 mL of chloroform is added thereto to prepare a sample solution. An indicator obtained by dissolving 0.275 g of soluble starch in 30 g of pure water is used as a starch indicator, and 20 mL of pure water, 10 mL of isopropyl alcohol, and 1 mL of the starch indicator are added thereto, and the mixture is stirred with a stirrer. An iodine solution is added dropwise, and the point at which a chloroform layer exhibits green is defined as an end point. In this case, the value given by the following formula is used as a thiol equivalent of the measurement sample.

Thiol equivalent (g/eq)=mass (g) of measurement sample×10,000/titration amount (mL) of iodine solution×factor of iodine solution

The thiol compound may contain a monofunctional thiol compound having one thiol group in one molecule.

Specific examples of monofunctional thiol compounds include hexanethiol, 1-heptanethiol, 1-octanethiol, 1-nonanethiol, 1-decanethiol, 3-mercaptopropionic acid, methyl mercaptopropionic acid, methoxybutyl mercaptopropionic acid, octyl mercaptopropionate, tridecyl mercaptopropionate, 2-ethylhexyl-3-mercaptopropionate, and n-octyl-3-mercaptopropionate.

The content of the thiol compound in the wavelength conversion resin composition (a total amount of the multi-functional thiol compound and monofunctional thiol compounds used as necessary) with respect to the total amount of the wavelength conversion resin composition is, for example, preferably 5 mass % to 50 mass %, more preferably 5 mass % to 40 mass %, still more preferably 10 mass % to 30 mass %, and particularly preferably 15 mass % to 25 mass %. In this case, the cured resin product forms a more dense cross-linked structure due to the ene-thiol reaction with the multi-functional (meth)acrylate compound, and moisture and heat resistance tends to be further improved.

The mass-based ratio of the multi-functional thiol compound to the total amount of the multi-functional thiol compound and monofunctional thiol compounds used as necessary is preferably 60 mass % to 100 mass %, more preferably 70 mass % to 100 mass %, and still more preferably 80 mass % to 100 mass %.

The mass-based content ratio of the multi-functional (meth)acrylate compound to that of the multi-functional thiol compound (multi-functional (meth)acrylate compound/multi-functional thiol compound) is preferably 0.5 to 10, more preferably 0.5 to 8.0, and still more preferably 0.5 to 6.0.

A ratio of a total number of carbon-carbon double bonds in the multi-functional (meth)acrylate compound to a total number of thiol groups of the thiol compound (a total amount of the multi-functional thiol compound and monofunctional thiol compounds used as necessary, preferably the multi-functional thiol compound) (total number of carbon-carbon double bonds/total number of thiol groups) is preferably 1.0 or more, more preferably 1.5 to 5.0, and still more preferably 2.0 to 4.0.

### (Photopolymerization Initiator)

The wavelength conversion resin composition may contain a photopolymerization initiator. The photopolymerization initiator is not particularly limited, and specific examples thereof include a compound that generates radicals according to emission of active energy rays such as UV rays.

Specific examples of photopolymerization initiators include aromatic ketone compounds such as benzophenone, N,N′-tetraalkyl-4,4′-diaminobenzophenone, 2-benzyl-2-dimethylamino-1-(4-morpholinophenyl)-butanone-1,2-methyl-1-[4-(methylthio)phen yl]-2-morpholino-propanone-1,4,4′-bis(dimethylamino)benzophenone (also referred to as “Michler's ketone”), 4,4′-bis(diethylamino)benzophenone, 4-methoxy-4′-dimethylaminobenzophenone, 1-hydroxycyclohexyl phenyl ketone,1-(4-isopropylphenyl)-2-hydroxy-2-methylpropan-1-one,1-(4-(2-hydroxyethoxy)-phenyl)-2-hydroxy-2-methyl-1-propan-1-one, and 2-hydroxy-2-methyl-1-phenylpropan-1-one; quinone compounds such as alkylanthraquinone and phenanthrenequinone; benzoin compounds such as benzoin and alkylbenzoin; benzoin ether compounds such as benzoin alkyl ether and benzoin phenyl ether; benzyl derivatives such as benzyl dimethyl ketal; 2,4,5-triarylimidazole dimers such as 2-(o-chlorophenyl)-4,5-diphenylimidazole dimer, 2-(o-chlorophenyl)-4,5-di(m-methoxyphenyl)imidazole dimer, 2-(o-fluorophenyl)-4,5-diphenylimidazole dimer, 2-(o-methoxyphenyl)-4,5-diphenylimidazole dimer, 2,4-di(p-methoxyphenyl)-5-phenylimidazole dimer, and 2-(2,4-dimethoxyphenyl)-4,5-diphenylimidazole dimer; acridine derivatives such as 9-phenylacridine and 1,7-(9,9′-acridinyl)heptane; oxime ester compounds such as 1,2-octanedione 1-[4-(phenylthio)-2-(O-benzoyloxime)], and ethanone 1-[9-ethyl-6-(2-methylbenzoyl)-9H-carbazol-3-yl]-1-(O-acetyloxime); coumarin compounds such as 7-diethylamino-4-methylcoumarin; thioxanthone compounds such as 2,4-diethylthioxanthone; and acylphosphine oxide compounds such as 2,4,6-trimethylbenzoyl-diphenyl-phosphine oxide, and 2,4,6-trimethylbenzoyl-phenyl-ethoxy-phosphine oxide. The wavelength conversion resin composition may contain one type of photopolymerization initiator alone or may contain two or more types of photopolymerization initiators in combination.

In consideration of curability, the photopolymerization initiator is preferably at least one selected from the group consisting of acylphosphine oxide compounds, aromatic ketone compounds, and oxime ester compounds, more preferably at least one selected from the group consisting of acylphosphine oxide compounds and aromatic ketone compounds, and still more preferably an acylphosphine oxide compound.

The content of the photopolymerization initiator in the wavelength conversion resin composition with respect to the total amount of the wavelength conversion resin composition is, for example, preferably 0.1 mass % to 5 mass %, more preferably 0.1 mass % to 3 mass %, and still more preferably 0.5 mass % to 1.5 mass %. When the content of the photopolymerization initiator is 0.1 mass % or more, the sensitivity of the wavelength conversion resin composition tends to be sufficient, and when the content of the photopolymerization initiator is 5 mass % or less, the influence of the wavelength conversion resin composition on the hue and decrease in the storage stability tend to be minimized.

### (Liquid Medium)

Preferably, the wavelength conversion resin composition does not contain a liquid medium or has a liquid medium content of 0.5 mass % or less. The liquid medium is a medium that is in a liquid state at room temperature (25° C.).

Specific examples of liquid mediums include ketone solvents such as acetone, methyl ethyl ketone, methyl-n-propyl ketone, methyl isopropyl ketone, methyl-n-butyl ketone, methyl isobutyl ketone, methyl-n-pentyl ketone, methyl-n-hexyl ketone, diethyl ketone, dipropyl ketone, diisobutyl ketone, trimethylnonanone, cyclohexanone, cyclopentanone, methylcyclohexanone, 2,4-pentanedione, and acetonylacetone; ether solvents such as diethyl ether, methyl ethyl ether, methyl-n-propyl ether, diisopropyl ether, tetrahydrofuran, methyltetrahydrofuran, dioxane, dimethyldioxane, ethylene glycol dimethyl ether, ethylene glycol diethyl ether, ethylene glycol di-n-propyl ether, ethylene glycol di-n-butyl ether, diethylene glycol dimethyl ether, diethylene glycol diethyl ether, diethylene glycol methyl ethyl ether, diethylene glycol methyl-n-propyl ether, diethylene glycol methyl-n-butyl ether, diethylene glycol di-n-propyl ether, diethylene glycol di-n-butyl ether, diethylene glycol methyl-n-hexyl ether, triethylene glycol dimethyl ether, triethylene glycol diethyl ether, triethylene glycol methyl ethyl ether, triethylene glycol methyl-n-butyl ether, triethylene glycol di-n-butyl ether, triethylene glycol methyl-n-hexyl ether, tetraethylene glycol dimethyl ether, tetraethylene glycol diethyl ether, tetraethylene glycol methyl ethyl ether, tetraethylene glycol methyl-n-butyl ether, tetraethylene glycol di-n-butyl ether, tetraethylene glycol methyl-n-hexyl ether, propylene glycol dimethyl ether, propylene glycol diethyl ether, propylene glycol di-n-propyl ether, propylene glycol di-n-butyl ether, dipropylene glycol dimethyl ether, dipropylene glycol diethyl ether, dipropylene glycol methyl ethyl ether, dipropylene glycol methyl-n-butyl ether, dipropylene glycol di-n-propyl ether, dipropylene glycol di-n-butyl ether, dipropylene glycol methyl-n-hexyl ether, tripropylene glycol dimethyl ether, tripropylene glycol diethyl ether, tripropylene glycol methyl ethyl ether, tripropylene glycol methyl-n-butyl ether, tripropylene glycol di-n-butyl ether, tripropylene glycol methyl-n-hexyl ether, tetrapropylene glycol dimethyl ether, tetrapropylene glycol diethyl ether, tetrapropylene glycol methyl ethyl ether, tetrapropylene glycol methyl-n-butyl ether, tetrapropylene glycol di-n-butyl ether, and tetrapropylene glycol methyl-n-hexyl ether; carbonate solvents such as propylene carbonate, ethylene carbonate, and diethyl carbonate; ester solvents such as methyl acetate, ethyl acetate, n-propyl acetate, isopropyl acetate, n-butyl acetate, isobutyl acetate, sec-butyl acetate, n-pentyl acetate, sec-pentyl acetate, 3-methoxybutyl acetate, methylpentyl acetate, 2-ethylbutyl acetate, 2-ethylhexyl acetate, 2-(2-butoxyethoxy)ethyl acetate, benzyl acetate, cyclohexyl acetate, methyl cyclohexyl acetate, nonyl acetate, methyl acetoacetate, ethyl acetoacetate, diethylene glycol methyl ether acetate, diethylene glycol monoethyl ether acetate, dipropylene glycol methyl ether acetate, dipropylene glycol ethyl ether acetate, glycol diacetate, methoxytriethylene glycol acetate, ethyl propionate, n-butyl propionate, isoamyl propionate, diethyl oxalate, di-n-butyl oxalate, methyl lactate, ethyl lactate, n-butyl lactate, n-amyl lactate, ethylene glycol methyl ether propionate, ethylene glycol ethyl ether propionate, ethylene glycol methyl ether acetate, ethylene glycol ethyl ether acetate, propylene glycol methyl ether acetate, propylene glycol ethyl ether acetate, propylene glycol propyl ether acetate, γ-butyrolactone, and γ-valerolactone; aprotic polar solvents such as acetonitrile, N-methylpyrrolidinone, N-ethylpyrrolidinone, N-propylpyrrolidinone, N-butylpyrrolidinone, N-hexylpyrrolidinone, N-cyclohexylpyrrolidinone, N,N-dimethylformamide, N,N-dimethylacetamide, and dimethyl sulfoxide; alcohol solvents such as methanol, ethanol, n-propanol, isopropanol, n-butanol, isobutanol, sec-butanol, t-butanol, n-pentanol, isopentanol, 2-methylbutanol, sec-pentanol, t-pentanol, 3-methoxybutanol, n-hexanol, 2-methylpentanol, sec-hexanol, 2-ethylbutanol, sec-heptanol, n-octanol, 2-ethylhexanol, sec-octanol, n-nonyl alcohol, n-decanol, sec-undecyl alcohol, trimethylnonyl alcohol, sec-tetradecyl alcohol, sec-heptadecyl alcohol, cyclohexanol, methylcyclohexanol, benzyl alcohol, ethylene glycol, 1,2-propylene glycol, 1,3-butylene glycol, diethylene glycol, dipropylene glycol, triethylene glycol, and tripropylene glycol; glycol mono ether solvents such as ethylene glycol monomethyl ether, ethylene glycol monoethyl ether, ethylene glycol monophenyl ether, diethylene glycol monomethyl ether, diethylene glycol monoethyl ether, diethylene glycol mono-n-butyl ether, diethylene glycol mono-n-hexyl ether, triethylene glycol monoethyl ether, tetraethylene glycol mono-n-butyl ether, propylene glycol monomethyl ether, dipropylene glycol monomethyl ether, dipropylene glycol monoethyl ether, and tripropylene glycol monomethyl ether; terpene solvents such as terpinene, terpineol, myrsen, aloocimene, limonene, dipentene, pinene, carvone, ocimene, and phellandrene; straight silicone oils such as dimethyl silicone oil, methylphenyl silicone oil, and methyl hydrogen silicone oil; modified silicone oils such as amino modified silicone oil, epoxy modified silicone oil, carboxy modified silicone oil, carbinol modified silicone oil, mercapto modified silicone oil, a different functional group modified silicone oil, polyether modified silicone oil, methylstyryl modified silicone oil, hydrophilic special modified silicone oil, higher alkoxy modified silicone oil, higher fatty acid modified silicone oil, and fluorine modified silicone oil; saturated aliphatic monocarboxylic acids having 4 or more carbon atoms such as butanoic acid, pentanoic acid, hexane acid, heptanoic acid, octanoic acid, nonanoic acid, decanoic acid, undecanoic acid, dodecanoic acid, tridecanoic acid, tetradecanoic acid, pentadecanoic acid, hexadecanoic acid, heptadecanoic acid, octadecanoic acid, nonadecanoic acid, eicosanoic acid, and eicosenoic acid; and unsaturated aliphatic monocarboxylic acid having 8 or more carbon atoms such as oleic acid, elaidic acid, linoleic acid, and palmitoleic acid. When the wavelength conversion resin composition contains a liquid medium, it may contain one type of liquid medium alone or two or more types of liquid mediums in combination.

### (Other Components)

The wavelength conversion resin composition may further contain other components such as a polymerization inhibitor, a silane coupling agent, a surfactant, an adhesion imparting agent, and an antioxidant. The wavelength conversion resin composition may contain one type of each of other components alone or two or more types thereof in combination.

In addition, the wavelength conversion resin composition may contain a (meth)allyl compound as necessary.

### (Method of Preparing Wavelength Conversion Resin Composition)

The wavelength conversion resin composition can be prepared by mixing a quantum dot phosphor, a filler, a multi-functional (meth)acrylate compound and a thiol compound, and as necessary, other components, by a general method. The quantum dot phosphor that is dispersed in a liquid medium is preferably mixed.

### (Applications of Wavelength Conversion Resin Composition)

The wavelength conversion resin composition can be appropriately used for film formation. In addition, the wavelength conversion resin composition can be appropriately used for forming a wavelength conversion member.

### EXAMPLES

Hereinafter, the present invention will be described in detail with reference to examples, but the present invention is not limited to these examples.

### Examples 1 to 7 and Comparative Examples 1 and 2

### (Preparation of Wavelength Conversion Resin Composition)

The components shown in Table 1 were mixed in formulation amounts (unit: parts by mass) shown in the table to prepare wavelength conversion resin compositions of Examples 1 to 7 and Comparative Examples 1 and 2. “-” in Table 1 means that the component was not added.

Here, regarding the multi-functional (meth)acrylate compound, tricyclodecane dimethanol diacrylate (A-DCP commercially available from Shin-Nakamura Chemical Co., Ltd.) was used.

In addition, regarding the multi-functional thiol compound, pentaerythritol tetrakis(3-mercaptopropionate) (PEMP commercially available from SC Organic Chemical Co., Ltd.) was used.

In addition, regarding the photopolymerization initiator, 2,4,6-trimethylbenzoyl-diphenyl-phosphine oxide (IRGACURE TPO commercially available from BASF) was used.

In addition, regarding a quantum dot phosphor that emits green light (quantum dot phosphor Green), a CdSe/ZnS (core/shell) dispersion (commercially available from Nanosys, Gen3.5 QD Concentrate) was used. Regarding the dispersion medium for the CdSe/ZnS (core/shell) dispersion, isobornyl acrylate was used. The CdSe/ZnS (core/shell) dispersion contained 90 mass % or more of isobornyl acrylate.

In addition, regarding a quantum dot phosphor that emits red light (quantum dot phosphor Red), an InP/ZnS (core/shell) dispersion (commercially available from Nanosys, Gen3.5 QD Concentrate) was used. Regarding the dispersion medium for the InP/ZnS(core/shell) dispersion, isobornyl acrylate was used. The InP/ZnS (core/shell) dispersion contained 90 mass % or more of isobornyl acrylate.

In addition, the following was used as the inorganic filler.

Titanium oxide (Ti-Pure R-706, average particle size of 0.36 μm commercially available from Chemours)

Alumina (AKP-30, average particle size of 0.27 μm commercially available from Sumitomo Chemical Company, Ltd.)

Crushed silica (AS-1, average particle size of 3.0 μm commercially available from Tatsumori Ltd.,)

Spherical silica (SO-C2, average particle size of 0.5 μm commercially available from Admatechs)

Here, the D10/D90 of all of the inorganic fillers was in a range of 0.04 to 0.25.

TABLE 1

| Items | | Example 1 | Example 2 | Example 3 | Example 4 | Example 5 |
|---|---|---|---|---|---|---|
| (Meth)acrylate | Tricyclodecane | 72.4 | 64.4 | 64.4 | 64.4 | 52.4 |
| compound | dimethanol diacrylate | | | | | |
| Multi-functional | Pentaerythritol | 18.1 | 16.1 | 16.1 | 16.1 | 13.1 |
| thiol compound | tetrakis(3-mercaptopropionate) | | | | | |
| Photopolymerization | 2,4,6-Trimethylbenzoyl- | 0.5 | 0.5 | 0.5 | 0.5 | 0.5 |
| initiator | diphenyl-phosphine | | | | | |
| | oxide | | | | | |
| Filler | Titanium oxide (R-706) | 5.0 | 15.0 | — | — | — |
| | Alumina (AKP-30) | — | — | 15.0 | — | — |
| | Silica (AS-1) | — | — | — | 15.0 | 30.0 |
| | Silica (SO-C2) | — | — | — | — | — |
| Quantum dot | Quantum dot phosphor | 2.5 | 2.5 | 2.5 | 2.5 | 2.5 |
| phosphor | Green (dispersion) | | | | | |
| | Quantum dot phosphor | 1.5 | 1.5 | 1.5 | 1.5 | 1.5 |
| | Red (dispersion) | | | | | |

| | | | | Comparative | Comparative |
|---|---|---|---|---|---|
| Items | | Example 6 | Example 7 | Example 1 | Example 2 |
| (Meth)acrylate | Tricyclodecane | 64.4 | 56.4 | 75.8 | 74.2 |
| compound | dimethanol diacrylate | | | | |
| Multi-functional | Pentaerythritol | 16.1 | 14.1 | 19.0 | 18.5 |
| thiol compound | tetrakis(3-mercaptopropionate) | | | | |
| Photopolymerization | 2,4,6-Trimethylbenzoyl- | 0.5 | 0.5 | 0.5 | 0.5 |
| initiator | diphenyl-phosphine | | | | |
| | oxide | | | | |
| Filler | Titanium oxide (R-706) | — | 20.0 | 0.7 | 2.8 |
| | Alumina (AKP-30) | — | — | — | — |
| | Silica (AS-1) | — | 5.0 | — | — |
| | Silica (SO-C2) | 15.0 | — | — | — |
| Quantum dot | Quantum dot phosphor | 2.5 | 2.5 | 2.5 | 2.5 |
| phosphor | Green (dispersion) | | | | |
| | Quantum dot phosphor | 1.5 | 1.5 | 1.5 | 1.5 |
| | Red (dispersion) | | | | |

### (Production of Wavelength Conversion Member)

Each of the wavelength conversion resin compositions obtained above was applied to a barrier film having an average thickness of 38 μm (commercially available from Dai Nippon Printing Co., Ltd.) (covering material) to form a coating film. A barrier film having a thickness of 38 μm (commercially available from Dai Nippon Printing Co., Ltd.) (covering material) was attached to the coating film, UV rays were emitted using a UV irradiation device (commercially available from Eye Graphics Co., Ltd.) (emission amount: 1,000 mJ/cm²), and thereby a wavelength conversion member in which the covering material was arranged on both surfaces of a cured product layer containing a cured resin product for wavelength conversion was obtained. The average thickness of the cured product layer was 75 μm.

### <Evaluation>

The following evaluation items were measured and evaluated using the wavelength conversion resin compositions and the wavelength conversion members obtained in Examples 1 to 7 and Comparative Examples 1 and 2. The results are shown in Table 2.

### (Evaluation of Appearance)

The appearance of each of the wavelength conversion members obtained above was evaluated as follows. First, a wavelength conversion member for evaluation obtained by cutting each wavelength conversion member into sizes with a width of 1,000 mm and a length of 1,500 mm was placed on a flat desk, and the float from the desk was measured using a ruler and used as a wrinkle height. In addition, for the wavelength conversion member for evaluation, the number of floats was visually counted and used as the number of wrinkles. The evaluation criteria for the wrinkle height and the number of wrinkles are as follows.

### —Evaluation Criteria (Wrinkle Height)—

A: 1.0 mm or less
B: more than 1.0 mm and 1.5 mm or less
C: more than 1.5 mm and 2.5 mm or less
D: more than 2.5 mm

### —Evaluation Criteria (Number of Wrinkles)—

A: 2 or less

### B: 3

### C: 4 or 5

D: 6 or more

### (Evaluation of Optical Properties)

Optical properties of each of the wavelength conversion members obtained above were evaluates as follows. The brightness of a wavelength conversion member for evaluation obtained by cutting each wavelength conversion member into sizes with a width of 100 mm and a length of 100 mm was measured using a brightness meter PR-655 (commercially available from Photo Research). In the brightness meter, a camera unit for recognizing optical properties was installed in the upper part, and a black mask, a brightness enhancing film (BEF) plate, a diffusion plate, and an LED light source were provided under the lens, and the measurement sample was set between the BEF plate and a diffusion plate, and the brightness was measured. The evaluation criteria for brightness are as follows.

### —Evaluation Criteria—

A: 1,100 or more
B: 1,000 or more and less than 1,100
C: 900 or more and less than 1,000
D: 600 or more and less than 900
E: less than 600

### (Evaluation of Curability)

The curability of each of the wavelength conversion resin compositions obtained above was evaluated as follows.

Specifically, it was checked whether there was a liquid portion in the wavelength conversion member obtained in the above (production of the wavelength conversion member). Under conditions of a UV emission amount of 1,000 mJ/cm², when there was no liquid portion in the wavelength conversion member, it was determined that the curability was favorable, and when there was a liquid portion in the wavelength conversion member, it was determined that the curability was poor.

TABLE 2

| | | | | | | | | | Comparative | Comparative |
|---|---|---|---|---|---|---|---|---|---|---|
| Item | | Example 1 | Example 2 | Example 3 | Example 4 | Example 5 | Example 6 | Example 7 | Example 1 | Example 2 |
| Appearance | Wrinkle | C | B | B | B | A | B | A | D | D |
| | height | | | | | | | | | |
| | Number of | C | A | A | A | A | B | A | D | D |
| | wrinkles | | | | | | | | | |
| Optical | Brightness | C | D | B | A | A | B | E | B | B |
| properties | | | | | | | | | | |
| Curability | Presence of | No | No | No | No | No | No | No | No | No |
| | liquid portion | | | | | | | | | |

As can be understood from Table 2, in Example 1 to Example 7, the appearance evaluation was better than that of Comparative Example 1 and Comparative Example 2. In particular, in Examples 4 and 5, when wavelength conversion members were produced using a wavelength conversion resin composition highly filled with a crushed silica filler having a large average particle size, the appearance and brightness were better than when wavelength conversion members were produced using the wavelength conversion resin compositions of Comparative Examples 1 and 2.

In addition, in Example 1 to Example 7, the curability of the wavelength conversion resin composition was favorable.

Priority is claimed on PCT/JP2019/010071, filed Mar. 12, 2019, the content of which is incorporated herein by reference.

All references, patent applications, and technical standards described in this specification are incorporated herein by reference to the same extent as if it were specifically and individually noted that the individual references, patent applications, and technical standards are incorporated by reference.

1. A wavelength conversion member comprising a quantum dot phosphor and a filler, and a cured resin product containing the quantum dot phosphor and the filler,
wherein a content of the filler with respect to a total amount of the cured resin product is 3 mass % or more.

2. The wavelength conversion member according to claim 1,
wherein the filler includes a low refractive index filler having a refractive index of 2.3 or less.

3. The wavelength conversion member according to claim 1,
wherein the filler contains at least one selected from the group consisting of silica, alumina, barium sulfate, zinc oxide, calcium carbonate and an organic filler.

4. The wavelength conversion member according to claim 1,
wherein an average particle size of the filler is 0.2 μm or more.

5. The wavelength conversion member according to claim 1,
wherein, in a volume cumulative distribution curve obtained by a laser diffraction scattering method, a ratio D10/D90 of a particle size D10 of the filler at a cumulative 10% from a small particle size side to a particle size D90 of the filler at a cumulative 90% from a small particle size side is 0.40 or less.

6. The wavelength conversion member according to claim 1,
wherein the total light transmittance of the cured resin product is 55% or more.

7. The wavelength conversion member according to claim 1,
wherein the cured resin product contains a sulfide structure.

8. The wavelength conversion member according to claim 1,
wherein the cured resin product contains a sulfide structure bonded to two carbon atoms and both the carbon atoms bonded to the sulfide structure are primary carbon atoms.

9. The wavelength conversion member according to claim 1, comprising
a covering material that covers at least a part of the cured resin product.

10. The wavelength conversion member according to claim 9,
wherein the covering material has a barrier property with respect to at least one of oxygen and water.

11. The wavelength conversion member according to claim 1,
wherein no titanium oxide is contained or a content of titanium oxide with respect to the total amount of the cured resin product is less than 5 mass %.

12. The wavelength conversion member according to claim 1,
wherein a content of the quantum dot phosphor with respect to the total amount of the cured resin product is 0.01 mass % to 1.0 mass %.

13. The wavelength conversion member according to claim 1,
wherein, when a content of the quantum dot phosphor with respect to the total amount of the cured resin product is set as X, and the content of the filler with respect to the total amount of the cured resin product is set as Y, Y/X is 7.0 or more.

14. The wavelength conversion member according to claim 1,
wherein the quantum dot phosphor includes a quantum dot phosphor R that emits red light and a quantum dot phosphor G that emits green light, and a content ratio of the quantum dot phosphor G with respect to the quantum dot phosphor R: quantum dot phosphor G/quantum dot phosphor R is 1.0 to 4.0.

15. A backlight unit comprising the wavelength conversion member according to claim 1, and a light source.

16. An image display device comprising the backlight unit according to claim 15.

17. A wavelength conversion resin composition comprising a quantum dot phosphor, a filler, a multi-functional (meth)acrylate compound and a thiol compound including a multi-functional thiol compound, and in which a content of the filler is 3 mass % or more.

18. The wavelength conversion resin composition according to claim 17,
wherein the filler includes a low refractive index filler having a refractive index of 2.3 or less.

19. The wavelength conversion resin composition according to claim 17,
wherein the filler is at least one selected from the group consisting of silica, alumina, barium sulfate, zinc oxide, calcium carbonate and an organic filler.

20. The wavelength conversion resin composition according to claim 17,
wherein an average particle size of the filler is 0.2 μm or more.

21. The wavelength conversion resin composition according to claim 17,
wherein, in a volume cumulative distribution curve obtained by a laser diffraction scattering method, a ratio D10/D90 of a particle size D10 of the filler at a cumulative 10% from a small particle size side to a particle size D90 of the filler at a cumulative 90% from a small particle size side is 0.40 or less.

22. The wavelength conversion resin composition according to claim 17,
wherein the multi-functional thiol compound has at least one thiol group bonded to a primary carbon atom.

23. The wavelength conversion resin composition according to claim 17,
wherein no titanium oxide is contained or a content of the titanium oxide with respect to a total amount of the wavelength conversion resin composition is less than 5 mass %.

24. The wavelength conversion resin composition according to claim 17,
wherein a content of the quantum dot phosphor with respect to a total amount of the wavelength conversion resin composition is 0.01 mass % to 1.0 mass %.

25. The wavelength conversion resin composition according to claim 17,
wherein, when a content of the quantum dot phosphor with respect to a total amount of the wavelength conversion resin composition is set as X, and the content of the filler with respect to the total amount of the wavelength conversion resin composition is set as Y, Y/X is 7.0 or more.

26. The wavelength conversion resin composition according to claim 17,
wherein the quantum dot phosphor includes a quantum dot phosphor R that emits red light and a quantum dot phosphor G that emits green light, and a content ratio of the quantum dot phosphor G with respect to the quantum dot phosphor R: quantum dot phosphor G/quantum dot phosphor R is 1.0 to 4.0.

27. The wavelength conversion resin composition according to claim 17,
wherein a ratio of a total number of carbon-carbon double bonds in the multi-functional (meth)acrylate compound to a total number of thiol groups in the thiol compound: total number of carbon-carbon double bonds/total number of thiol groups is 1.0 or more.
